(19) United States
(12) Patent Application Publication
(10) Pub. No.: US 2025/0208201 A1
(43) Pub. Date: Jun. 26, 2025

(54) COPLANARITY ASSIST UNIT, SEMICONDUCTOR TESTING APPARATUS INCLUDING THE COPLANARITY ASSIST UNIT AND METHOD OF SETTING COPLANARITY

(71) Applicant: Taiwan Semiconductor Manufacturing Company Limited, Hsinchu (TW)

(72) Inventors: Jyun-Cheng Huang, Tainan City (TW); Chin-Ta Chen, Kaohsiung City (TW)

(21) Appl. No.: 18/393,846

(22) Filed: Dec. 22, 2023

(51) Int. Cl. G01R 31/28; G01R 1/073

(52) U.S. Cl. CPC G01R 31/2887; G01R 1/07342

(57) ABSTRACT

A coplanarity assist unit includes a plurality of distance sensors mounted on at least one of a lower body or a upper body at a plurality of locations, respectively, and configured to detect a distance between the lower body and the upper body at the plurality of locations, and a coplanarity assistant configured to determine whether coplanarity exists between the lower body and the upper body and assist with setting coplanarity between the lower body and the upper body based on an output of the plurality of distance sensors.

### BACKGROUND

A semiconductor testing apparatus (e.g., semiconductor test equipment) may be used to test a semiconductor device such as a semiconductor wafer that includes one or more integrated circuits formed thereon. In operation, the semiconductor testing apparatus may transmit one or more electrical test signals to the semiconductor device. The semiconductor device may transmit one or more output signals in response to the electrical test signal. The semiconductor testing apparatus may compare the output signals against expected values to determine whether the semiconductor device operates as specified in the design specifications for the semiconductor device.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a schematic block diagram of a coplanarity assist unit (docking planarity digitized mechanism) according to one or more embodiments.

FIG. 2A is a vertical cross-sectional view of the semiconductor testing apparatus according to one or more embodiments.

FIG. 2B is a plan view (e.g., bottom-up view) of the tester head of the semiconductor testing apparatus according to one or more embodiments.

FIG. 2C is a detailed vertical cross-sectional view of the distance sensors in the semiconductor testing apparatus according to one or more embodiments.

FIG. 3A is a plan view of a first alternative layout of the distance sensors 20 and guide holes on the bottom surface of the tester head according to one or more embodiments.

FIG. 3B is a plan view of a second alternative layout of the distance sensors and guide holes on the bottom surface of the tester head according to one or more embodiments.

FIG. 3C is a plan view of a third alternative layout of the distance sensors and guide holes on the bottom surface of the tester head according to one or more embodiments.

FIG. 3D is a plan view of a fourth alternative layout of the distance sensors and guide holes on the bottom surface of the tester head according to one or more embodiments.

FIG. 4A is a vertical cross-sectional view of the first alternative design of the semiconductor testing apparatus according to one or more embodiments.

FIG. 4B is a plan view (e.g., top-down view) of the prober in the first alternative design of the semiconductor testing apparatus according to one or more embodiments.

FIG. 4C is a detailed vertical cross-sectional view of the distance sensors in the first alternative design of the semiconductor testing apparatus according to one or more embodiments.

FIG. 5 is a schematic block diagram of a first alternative design of the coplanarity assist unit according to one or more embodiments.

FIG. 6A is a vertical cross-sectional view of a second alternative design of the semiconductor testing apparatus according to one or more embodiments.

FIG. 6B is a vertical cross-sectional view of the electromechanical planarity adjuster according to one or more embodiments.

FIG. 7 is a flowchart illustrating a method of setting coplanarity according to one or more embodiments.

### DETAILED DESCRIPTION

The following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor testing apparatus may include a tester head (e.g., movable tester head) upon which the semiconductor device to be tested may be mounted. The tester head may resemble the structure of a cantilever beam. The tester head may be locked/unlocked to adjust the tester head planarity. The semiconductor device may be referred to as a device under test (DUT). The semiconductor testing apparatus may also include a prober (wafer prober) on which a probe card may be docked (e.g., mounted). The tester head may be positioned over the prober so that the DUT is aligned with the probe card.

The probe card may serve as an interface between the semiconductor testing apparatus and the DUT. A wide variety of probe card types may be used. The type of probe card selected may be based on the specific requirements of the DUT. For example, a vertical probe card may include vertically-oriented probes which are particularly useful for probing extremely small or densely packed semiconductor devices. A cantilever probe card may include a set of fine, spring-loaded probes (typically made of tungsten or other conductive materials) mounted on a flexible substrate. A micro-electromechanical systems (MEMS) probe card may include micro-fabricated structures and tiny probes and may be well-suited for testing advanced ICs with high pin counts and small pitches. A ceramic probe card may be heat-resistant and often used in high-frequency applications where signal integrity is critical. A membrane probe card may have a flexible, thin membrane structure designed for testing very fine-pitch, high-density semiconductor devices, such as advanced microprocessors, memory chips, or system-on-chip (SoC) devices.

Some types of probe cards (e.g., membrane probe cards) may be especially sensitive to tester docking planarity. Currently, the entire docking interface, prober and probe card planarity may be detected by tools regularly. However, the planarity may vary while re-docking the tester head. There may be no digital data provided to show the docking planarity performance. Thus, tester docking planarity may need to be manually checked.

Re-docking may involve tester head horizontal movement, vertical movement and rotational motion. The docking planarity of the tester head may vary after tester head re-docking (e.g., tester head horizontal movement, vertical movement and rotation motion). Docking planarity may only be visually inspected and cannot be detected by digitized mechanism.

The semiconductor testing apparatus may include a visual planarity gauge (VPG) that checks the planarity of the prober head plane by using prober camera alignment data. The level difference of the tester may be about 0.1 mm, and the VPG difference may be in a range from 3 μm to 4 μm (representing a level run of 3 μm to 4 μm) which may cause burnt needles or a burn die on high performance computing (HPC)/high pic count/high power devices.

At least one embodiment of the present disclosure may include a coplanarity assist unit (e.g., docking planarity digitized mechanism). The coplanarity assist unit may help to make docking planarity visible (i.e., the degree in which two planes of an upper body and a lower body are parallel to one another). The coplanarity assist unit may also effectively and efficiently quantify docking performance. At least one embodiment may include a semiconductor testing apparatus including the coplanarity assist unit. The semiconductor testing apparatus may include, for example, a semiconductor automatic test equipment (ATE). At least one embodiment may include a method of setting coplanarity.

The semiconductor testing apparatus may include a prober having one or more prober head planes. The probe card may be mounted on the prober. The prober may also include a plurality of (e.g., three or more) guide pins located in the prober head plane. The semiconductor testing apparatus may also include a tester head located over the prober. The tester head may include one or more DUT sites for mounting a DUT. The tester head may also include a plurality of guide holes into which the guide pins may be inserted.

The coplanarity assist unit may include a plurality of distance sensors for detecting a distance between the tester head and the prober. The coplanarity assist unit may determine (e.g., automatically determining) the tester docking planarity based on an output of the distance sensors. The distance sensors may be supported by a plurality sensor support frames, respectively. The sensor support frames and distance sensors may be located on the tester head and/or on the prober. The distance sensors may include, for example, a laser, ultrasonic sensor, infrared sensor, inductive sensor, light-emitting diode (LED), light detection and ranging (LIDAR), vertical cavity surface emitting laser (VCSEL), etc.

In at least one embodiment, the distance sensors may be installed so as to be coplanar with the tester head. The distance sensors may include, for example, a laser rangefinder installed on the tester head. In this case, the distance sensor may directly detect the distance between prober head plane and tester head after docking.

In at least one embodiment, the distance sensors may be installed so as to be coplanar with the prober head plane. The distance sensors may include a laser rangefinder installed on the prober head plane. In this case, the distance sensor may also directly detect the distance between prober head plane and tester head after docking.

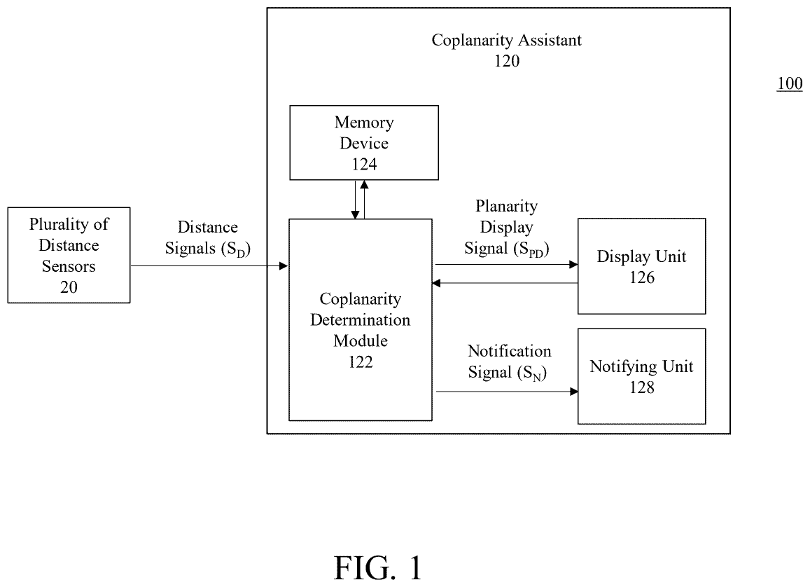

FIG. 1 is a schematic block diagram of a coplanarity assist unit 100 (docking planarity digitized mechanism) according to one or more embodiments. As illustrated in FIG. 1, the coplanarity assist unit 100 may include a plurality of distance sensors 20 configured to detect a distance between a lower body and an upper body, and a coplanarity assistant 120 configured to assist with setting coplanarity between the lower body and the upper body based on an output of the distance sensors 20.

The distance sensors 20 may be mounted, for example, on the lower body and/or the upper body at a plurality of locations. In at least one embodiment, the distance sensors 20 may include one or more of a laser sensor, an ultrasonic sensor, an infrared sensor, an inductive sensor, a light-emitting diode (LED) sensor, a light detection and ranging (LIDAR) device, or a vertical cavity surface emitting laser (VCSEL) sensor. Other types of distance sensors are within the contemplated scope of disclosure.

The output of the distance sensors 20 may include a plurality of distance signals (Sp) transmitted from the plurality of distance sensors 20, respectively. In at least one embodiment, the coplanarity assist unit 100 may include a wired connection between the distance sensors 20 and the coplanarity assistant 120. In such an embodiment, the distance sensors 20 may transmit the distance signals (SD) to the coplanarity assistant 120 by the wired connection.

In at least one embodiment, one or more of the distance sensors 20 may include a wireless transmitter for wirelessly transmitting the distance signals (SD). In such an embodiment, the distance sensors 20 may be wirelessly connected to the coplanarity assistant 120 by a near-field wireless communication technology. That is, one or more of the distance signals (SD) may be wireless signals which may eliminate the need for the wired connection between the distance sensors 20 and the coplanarity assistant 120.

The coplanarity assistant 120 may be implemented, for example, in the form of a computer, laptop, server, handheld device, etc. The coplanarity assistant 120 may include a wireless receiver (not shown) for receiving the distance signals (SD) in the form of wireless signals. In at least one embodiment, the coplanarity assistant 120 may be designed to receive the distance signals (SD) from the distance sensors 20 by a wired connection and/or by a wireless connection. In at least one embodiment, the coplanarity assistant 120 may also include an A/D converter (not shown) which may receive one or more of the distance signals (SD). The A/D converter may convert the distance signals (SD) from an analog to digital format, to allow the coplanarity assistant 120 to process the distance signals (SD) as digital signals.

As illustrated in FIG. 1, the coplanarity assistant 120 may also include a coplanarity determination module 122. The coplanarity determination module 122 may include a processor such as a central processing unit (CPU). The coplanarity determination module 122 may identify values of the distance signals (SD) as distance signal values and perform one or more operations on the distance signal values. In at least one embodiment, the coplanarity determination module 122 may perform one or more operations on the distance signal values to determine whether the lower body and the upper body are coplanar. The coplanarity determination module 122 may use other data in addition to the distance signal values to determine whether the lower body and the upper body are coplanar.

The coplanarity assistant 120 may also include a memory device 124 such as random access memory (RAM), read-only memory (ROM), etc. The memory device 124 may be communicatively coupled to the coplanarity determination module 122. The coplanarity determination module 122 may access the memory device 124 to store data used or generated by the operations performed on the distance signal values. In at least one embodiment, the memory device 124 may store instructions to be executed by the coplanarity determination module 122. In at least one embodiment, the memory device 124 may store data to be used by the coplanarity determination module 122 in executing the instructions. In at least one embodiment, the memory device 124 may store other data such as planarity-related history data that may be generated by the coplanarity determination module 122.

The memory device 124 may store data and/or instructions in the form of a lookup table and/or a calculation table. These tables may be accessed by the coplanarity determination module 122 and used by the coplanarity determination module 122 to execute instructions or control various operations in the coplanarity assistant 120.

The coplanarity determination module 122 may also be connected to an operator control signal line (not shown) for controlling an operation of the coplanarity determination module 122. An operator (e.g., user) may use an input device (e.g., keyboard, mouse, touchpad, etc.) to input an operating instruction over the operator control signal line to the coplanarity determination module 122. The operator may also input software updates, adjust an operating condition (e.g., coplanarity tolerance), etc. over the operator control signal line.

In embodiments in which the coplanarity determination module 122 determines that coplanarity is beyond a threshold amount (i.e., coplanarity does not exist) between the lower body and the upper body, then the coplanarity determination module 122 may determine what corrective action may be taken to set a coplanarity between the lower body and upper body based on the distance signals (SD). The corrective action may dictate, for example, that one side of the upper body should be raised by a given distance or lowered by a given distance to bring the lower body and upper body into coplanarity. The coplanarity determination module 122 may then generate adjustment data corresponding to the corrective action.

As illustrated in FIG. 1, the coplanarity assistant 120 may also include a display unit 126 communicatively coupled to the coplanarity determination module 122. The display unit 126 may include, for example, a light emitting diode (LED) display unit, a liquid crystal display (LCD) display unit, etc. In at least one embodiment, the display unit 126 may include a touch screen and an operator may use the touch screen of the display unit 126 to transmit data and/or instructions to the coplanarity determination module 122. Other types of display units are within the contemplated scope of disclosure.

The coplanarity determination module 122 may include a transmitter for transmitting one or more planarity display signals (SPD) to the display unit 126 based on the distance signals (SD). The display unit 126 may generate one or more display screens based on the planarity display signals (SPD). Based on the planarity display signals (SPD), the display unit 126 may display a message indicating that coplanarity has been set or has not been set between the lower body and the upper body. Based on the planarity display signals (SPD), the display unit 126 may also display the adjustment data generated by the coplanarity determination module 122 indicating how the planarity of the upper body may be adjusted in order to bring the lower body and the upper body into coplanarity. Based on the planarity display signals (SPD), the display unit 126 may also display distance data indicating a distance detected by one or more of the distance sensors 20. The display unit 126 may also display a graphic identifying a location of the distance sensors 20 associated with the distance data.

In at least one embodiment, the coplanarity assistant 120 may include a wired connection between the coplanarity determination module 122 and the display unit 126. In that case, the coplanarity determination module may transmit the planarity display signals (SPD) to the display unit 126 by the wired connection.

In at least one embodiment, the coplanarity determination module 122 may include a wireless transmitter for wirelessly transmitting the planarity display signals (SPD) to the display unit 126, and the display unit 126 may include a wireless receiver for wirelessly receiving the planarity display signals (SPD). In this case, the coplanarity determination module 122 may be wirelessly connected to the display unit 126 by a wireless technology such as Bluetooth®, Zigbee® or other near-field communication technology. That is, one or more of the planarity display signals (SPD) may be wireless signals which may eliminate the need for the wired connection between the coplanarity determination module 122 and the display unit 126.

As further illustrated in FIG. 1, the coplanarity determination module 122 may transmit a notification signal (SN) to notify the operator that coplanarity between the upper body and the lower body does exist or does not exist. The coplanarity assistant 120 may also include a notifying unit 128 that receives the notification signal (SN) from the coplanarity determination module 122. The coplanarity determination module 122 may transmit the notification signal (SN) to the notifying unit 128 by a wired connection and/or by a wireless connection as described above with respect to the planarity display signal.

The notifying unit 128 may provide a visual notification that coplanarity between the upper body and the lower body does exist or does not exist. For example, the notifying unit 128 may include one or more light emitting devices (e.g., LEDs) emitting one color (e.g., green) to indicate coplanarity exists between the upper body and the lower body, and another color (e.g., red) to indicate coplanarity does not exist between the upper body and the lower body. The notifying unit 128 may alternatively or additionally provide an audible notification that coplanarity between the upper body and the lower body does exist or does not exist. For example, the notifying unit 128 may include one or more sound generators generating one sound to indicate coplanarity exists between the upper body and the lower body, and another sound to indicate coplanarity does not exist between the upper body and the lower body. It should be noted that the display unit 126 and the notifying unit 128 may be combined into one unit that combines the features of both the display unit 126 and the notifying unit 128.

In at least one embodiment, the coplanarity determination module 122 may continuously update a display of the adjustment data on the display unit 126 to reflect an adjustment to the planarity of the upper body by an operator. It should be noted that the term “continuously” may be understood to mean that the adjustment data is updated periodically and the period of update is short enough (e.g., less than one second) that the update of adjustment data displayed on the display unit 126 may appear instantaneous to the operator. Thus, as the operator is adjusting the planarity of the upper body, the operator may observe the adjustment data changing on the display unit 126 to reflect the adjustments made by the operator.

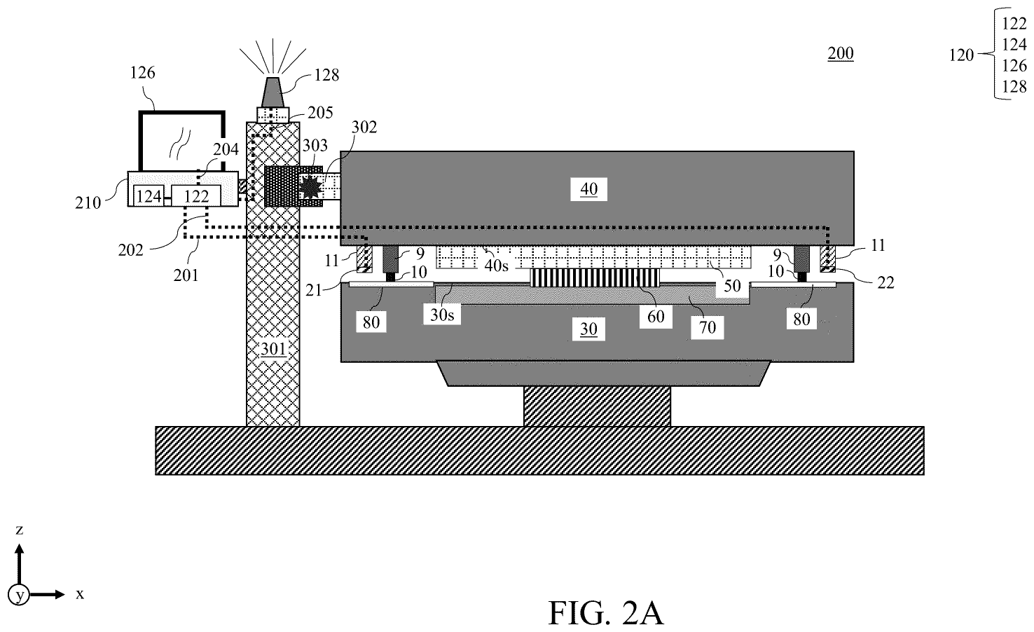

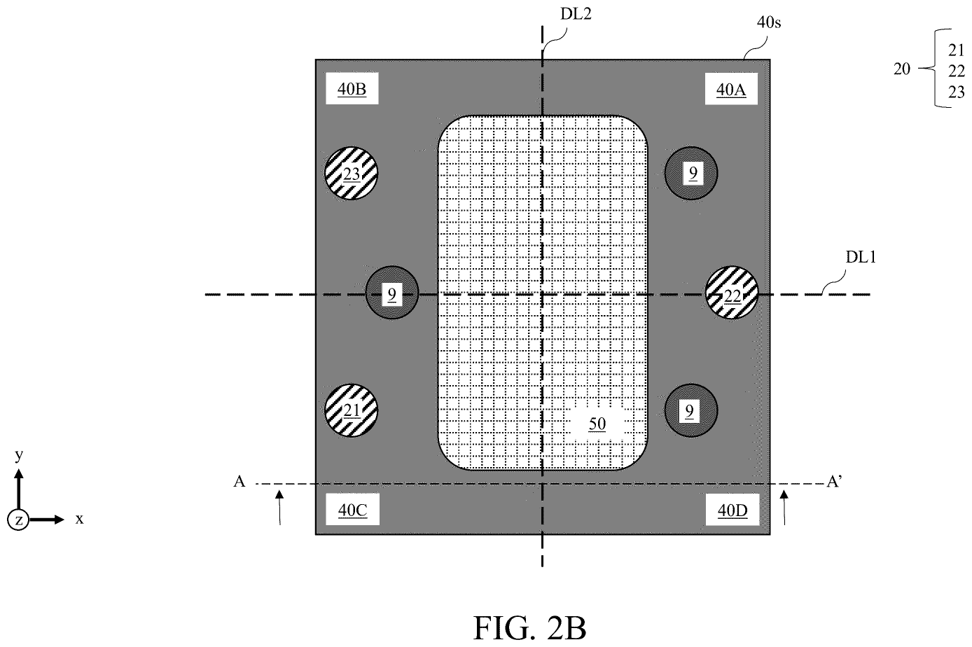

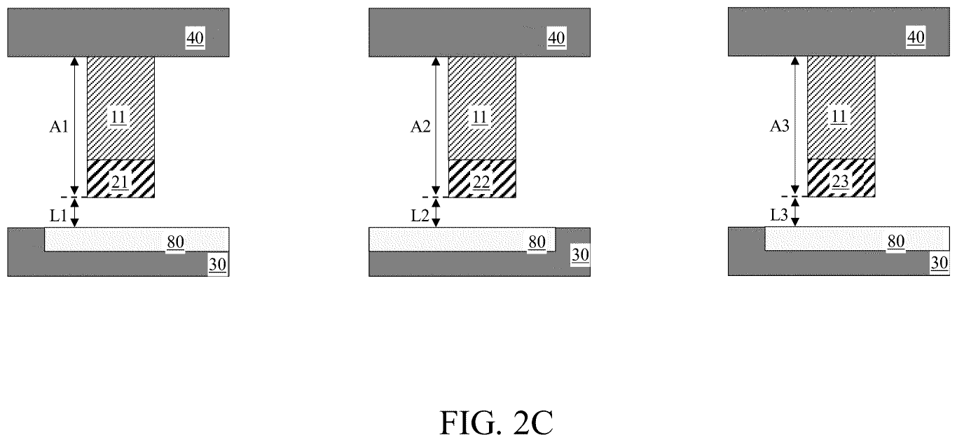

FIGS. 2A-2C are various views of a semiconductor testing apparatus 200 (automated test equipment) including the coplanarity assist unit 100 according to one or more embodiments. FIG. 2A is a vertical cross-sectional view of the semiconductor testing apparatus 200 according to one or more embodiments. FIG. 2B is a plan view (e.g., bottom-up view) of the tester head 40 (upper body) of the semiconductor testing apparatus 200 according to one or more embodiments. The vertical cross-sectional view in FIG. 2A is in the y-direction along the line A-A′ in FIG. 2B. FIG. 2C is a detailed vertical cross-sectional view of the distance sensors in the semiconductor testing apparatus 200 according to one or more embodiments.

The semiconductor testing apparatus 200 may include a prober 30 (lower body) or wafer prober on which a probe card 70 may be docked (e.g., mounted). The prober 30 may include one or more prober head planes 80 located at an upper surface 30s of the prober 30. An upper surface of the prober head planes 80 may be substantially coplanar with an upper surface 30s of the prober 30. In at least one embodiment, the upper surface of the prober head planes 80 may be substantially coextensive with the upper surface 30s of the prober 30. In at least one embodiment, the prober 30 may include a prober head plane 80 associated with each of the distance sensors and each of the guide holes 9. In at least one embodiment, the prober 30 may include one prober head plane 80 having a ring shape formed continuously around the upper surface 30s of the prober 30.

In at least one embodiment, the prober 30 may have a substantially fixed position. In particular, the upper surface 30s of the prober 30 may have a substantially fixed planarity. The semiconductor testing apparatus 200 may include a visual planarity gauge (VPG) (not shown) which may be used to check a planarity of the prober head planes 80 by using prober camera alignment data.

The semiconductor testing apparatus 200 may also include a tester head 40 located over the prober 30. A device under test (DUT) 50 may be mounted to a lower surface 40s of the tester head 40. The DUT 50 may include a semiconductor device including one or more integrated circuits to be tested in semiconductor testing apparatus 200.

The tester head 40 may be positioned over the prober 30 so that the DUT 50 is aligned with the probe card 70. To assist with alignment, the tester head 40 may include three or more guide holes 9 and the prober 30 may include three or more guide pins 10. Each of the guide holes 9 on the tester head 40 may have an associated guide pin 10 on the prober 30.

As illustrated in FIG. 2A, the guide holes 9 may project down from the lower surface 40s of the tester head 40. The guide pins 10 may be located on the prober head plane 80 and project upward from the prober head plane 80. As the tester head 40 is moved down toward the prober 30, the guide pins 10 may be inserted into the guide holes 9, respectively. A diameter of the guide pins 10 may be slightly less than a diameter of the guide holes 9 so that a snug fit may be provided between the guide pins 10 in the guide holes 9, respectively.

The tester head 40 may be movably fixed to a mounting structure 301 by a bracket 302 extending horizontally from the mounting structure 301. The bracket may allow movement of the tester head 40 including horizontal movement (e.g., laterally in the x-y plane), vertical movement (e.g., up and down in the z-plane) and rotational movement. The rotational movement of the tester head 40 may be used to adjust a planarity of the tester head 40. For example, rotational movement may include one side of the tester head 40 being moved down in the z-direction and an opposing side of the tester head 40 being raised in the z-direction.

The bracket 302 may include a lock and release bolt 303 that may be loosed to release the tester head 40 allowing an operator to move (e.g., rotate) the tester head 40 to adjust a planarity of the tester head 40. The lock and release bolt 303 may also be tightened by the operator to fix a position of the tester head 40 (e.g., fix the planarity of the tester head 40).

A bridge beam 60 may be located on the probe card 70 and between the DUT 50 and the probe card 70. The bridge beam 60 may lock the probe card 70 to the prober 30. The bridge beam 60 may provide additional stiffness and a mechanism through which the probing force can be transferred efficiently to the prober 30.

The tester head 40 may transmit one or more electrical test signals to the DUT 50 (e.g., to the integrated circuits in the DUT 50). The DUT 50 may transmit one or more output signals in response to the electrical test signal. The semiconductor testing apparatus 200 may compare the output signals against expected values to determine if the DUT 50 operates as specified in its design specifications.

The probe card 70 may serve as an interface between the semiconductor testing apparatus 200 and the DUT 50. The probe card 70 may enable the tester head 40 to send the electrical signals to the DUT 50 and measure the response of the DUT 50, which may include signals generated by the DUT 50 or its electrical characteristics.

The probe card 70 may have a design that is unique to the DUT 50. The probe card 70 may include one or more electrical contacts (not shown) for contacting the DUT 50. The electrical contacts may include, for example, an array of tiny, spring-loaded probe tips or needles that make contact with electrical contact points (not shown) on the DUT 50. The electrical contact points may include metal pads, pins, or bumps on the surface of the DUT 50.

The probe card 70 may be configured to ensure that the electrical contacts (e.g., probe tips) on the probe card 70 contact corresponding electrical contact points on the DUT 50. The electrical contacts (e.g., probes) on the probe card may be spring-loaded so that they exert a controlled amount of force when making contact with the electrical contact points on the DUT 50. This may help to ensure that the electrical contacts create a reliable electrical connection and compensate for any variations in the height or planarity of the DUT 50. The probe card 70 may include, for example, a vertical probe card, cantilever probe card, micro-electromechanical systems (MEMS) probe card, ceramic probe card, membrane probe card, etc.

As further illustrated in FIG. 2A, the semiconductor testing apparatus 200 may include the coplanarity assist unit 100. The coplanarity assist unit 100 may help to make docking planarity visible and may effectively and efficiently quantify docking performance in the semiconductor testing apparatus 200.

The coplanarity assist unit 100 may include a first distance sensor 21, a second distance sensor 22 and a third distance sensor 23 (see FIG. 2B). More distance sensors may be included within the contemplated scope of disclosure. The first distance sensor 21, second distance sensor 22 and third distance sensor 23 may be referred to collectively as distance sensors 20. Each of the first distance sensor 21, second distance sensor 22 and third distance sensor 23 may be located on a sensor support frame 11 that projects down from the lower surface 40s of the tester head 40.

A distance between the distance sensors 20 may be greater than a maximum size of site of the probe card 70 in the prober 30. In at least one embodiment, a distance between the distance sensors 20 may be at least 50% greater than a maximum size of site of the probe card 70 in the prober 30. For example, as illustrated in FIG. 2A, a distance in the x-direction between the first distance sensor 21 and the second distance sensor 22 may be greater than a width of the probe card 70 in the x-direction.

The various features of the coplanarity assistant 120 may be mounted on the mounting structure 301. In particular, the planarity determination module 122 and memory device 124 may be located in a housing structure 210 mounted to the mounting structure 301. The display unit 126 may be located on the housing structure 210. The notifying unit 128 (e.g., a light-emitting device) may be mounted on the mounting structure 301 near the display unit 126. It should be noted that the location of the various features of the coplanarity assistant 120 in FIG. 2A are merely illustrative and should not be considered limiting. In particular, the coplanarity assistant 120 may be located at other locations near the tester head 40 or may alternatively be located at a remote location away from the tester head 40.

The first distance sensor 21 may transmit a first distance signal over a first wiring line 201 to the coplanarity determination module 122. The first wiring line 201 may extend through the tester head 40 into the sensor support frame 11 supporting the first distance sensor 21 to contact the first distance sensor 21. The second distance sensor 22 may transmit a second distance signal over a second wiring line 202 to the coplanarity determination module 122. The second wiring line 202 may also extend through the tester head 40 into the sensor support frame 11 supporting the second distance sensor 22 to contact the second distance sensor 22. The third distance sensor 23 may transmit a third distance signal over a third wiring line (not shown) to the coplanarity determination module 122. The third wiring line may also extend through the tester head 40 into the sensor support frame (not shown) supporting the third distance sensor 23 to contact the third distance sensor 23.

The coplanarity determination module 122 may transmit a planarity display signal (SPD) to the display unit 126 over a fourth wiring line 204 and transmit a notification signal (SN) to the notifying unit 128 over a fifth wiring line 205. It should be noted that each of the first distance signal, second distance signal, third distance signal, planarity display signal (SPD) and notification signal (SN) may alternatively be transmitted and received in the coplanarity assist unit 100 by a wireless connection.

Referring to FIG. 2B, the lower surface 40s of the tester head 40 may be divided into four quadrants by a first dividing line DL1 extending in the x-direction and a second dividing line DL2 extending in the y-direction. The first dividing line DL1 and second dividing line DL2 may intersect at a centerpoint of the lower surface 40s of the tester head 40. The first dividing line DL1 and second dividing line DL2 may divide the lower surface 40s into a first quadrant 40A, a second quadrant 40B, a third quadrant 40C and a fourth quadrant 40D. The first quadrant 40A, second quadrant 40B, third quadrant 40C and fourth quadrant 40D may have substantially the same shape and substantially the same area. The mounting site for mounting the DUT 50 may be located in central region of the lower surface 40s. The centerpoint of the DUT 50 may be co-located with the centerpoint of the lower surface 40s of the tester head 40.

The distance sensors in the semiconductor testing apparatus 200 may have an arrangement and shape designed by layout. As illustrated in FIG. 2B, the first distance sensor 21 may be located in the third quadrant 40C. The second distance sensor 22 may be located on the dividing line DL1 between the first quadrant 40A and the fourth quadrant 40D. The third distance sensor 23 may be located in the second quadrant 40B.

In at least one embodiment, the number of guide holes 9 in the semiconductor testing apparatus 200 may be the same as the number of distance sensors. As illustrated in FIG. 2B, the semiconductor testing apparatus 200 may include three guide holes 9. One of the guide holes 9 may be located in the fourth quadrant 40D. Another of the guide holes 9 may be located in the first quadrant 40A. Another of the guide holes 9 may be located on the first dividing line DL1 between the second quadrant 40B and the third quadrant 40C. The guide holes 9 on the tester head 40 may be substantially aligned with the guide pins 10 on the prober 30 in the z-direction.

Referring to FIG. 2C, a vertical cross-sectional view of the first distance sensor 21, second distance sensor 22 and third distance sensor 23 is shown. As illustrated in FIG. 2C, the first distance sensor 21 and the sensor support frame 11 on which the first distance sensor 21 is mounted may have a first combined length A1. The first distance sensor 21 may detect a first separation distance L1 between the prober head plane 80 and the tester head 40 (e.g., the first separation distance L1 between the prober head plane 80 and the first distance sensor 21) at a first location.

The second distance sensor 22 and the sensor support frame 11 on which the second distance sensor 22 is mounted may have a second combined length A2. The second distance sensor 22 may detect a second separation distance L2 between the prober head plane 80 and the tester head 40 (e.g., the second separation distance L2 between the prober head plane 80 and the second distance sensor 22) at a second location.

The third distance sensor 23 and the sensor support frame 11 on which the third distance sensor 23 is mounted may have a third combined length A3. The third distance sensor 23 may detect a third separation distance L3 between the prober head plane 80 and the tester head 40 (e.g., the third separation distance L3 between the prober head plane 80 and the third distance sensor 23) at a third location.

The coplanarity determination module 122 may perform one or more calculations on the first distance signal from the first distance sensor 21, the second distance signal from the second distance sensor 22 and the third distance signal from the third distance sensor 23 to determine whether coplanarity has been achieved (e.g., whether the tester head 40 and the prober 30 are substantially coplanar). In particular, values for the first combined length A1 (e.g., for the first distance sensor 21 and the sensor support frame 11 on which it is mounted), the second combined length A2 (e.g., for the second distance sensor 22 and the sensor support frame 11 on which it is mounted) and the third combined length A3 (e.g., for the third distance sensor 23 and the sensor support frame 11 on which it is mounted) may be stored in the memory device 124. The coplanarity determination module 122 may retrieve first combined length A1, second combined length A2, and third combined length A3 from the memory device 124. The coplanarity determination module 122 may then add the first combined length A1 with the first separation distance L1 to produce a first sum, add the second combined length A2 with the second separation distance L2 to produce a second sum, and add the third combined length A3 with the third separation distance L3 to produce a third sum.

The coplanarity determination module 122 may then compare the first sum to the second sum and the third sum. In instances in which the coplanarity determination module 122 determines, based on the comparison, that first sum is substantially equal (i.e., within a threshold measurement distance) to the second sum and third sum (e.g., L1+A1=L2+A2=L3+A3), then the coplanarity determination module 122 may transmit a planarity display signal (SPD) to the display unit 126 to display a message that coplanarity exists between the tester head 40 and the prober 30 and/or that directing the operator to lock the tester head 40 into position using the lock and release bolt 303. The coplanarity determination module 122 may also transmit a notification signal (SN) to the notifying unit 128 to generate, for example, a green light to indicate that coplanarity exists between the tester head 40 and the prober 30.

On the other hand, in instances in which the coplanarity determination module 122 determines, based on the comparison, that first sum not substantially equal (i.e., beyond a threshold measurement distance) to the second sum and/or the third sum (e.g., L1+A1L2+A2 and/or L1+A1L3+A3), then the coplanarity determination module 122 may transmit a planarity display signal (SPD) to the display unit 126 to display a message that coplanarity does exist between the tester head 40 and the prober 30 and/or that directing the operator to adjust a planarity of the tester head 40 including specific instructions on how to adjust the planarity of the tester head 40 (e.g., raise left side of tester head 40, lower front side of tester head 40, etc.). The coplanarity determination module 122 may also transmit a notification signal (SN) to the notifying unit 128 to generate, for example, a red light to indicate that coplanarity does not exist between the tester head 40 and the prober 30.

The coplanarity assist unit 100 may help to determine docking coplanarity between prober 30 and tester 40 to avoid a quality event such as a burnt tip, tip damage, tip lifetime (e.g., tip expiration), etc. The coplanarity assist unit 100 may digitize the docking performance by utilizing the distance sensors 20. In at least one embodiment, the distance sensors 20 (e.g., sensor light) may determine a valid docking planarity while re-docking the tester head, thereby making the docking planarity digitized and easily preformed.

The coplanarity assist unit 100 may provide several advantages. The coplanarity assist unit 100 may achieve the fault defect classification (FDC) function of real-time monitoring of the prober 30/tester head 40 coplanarity to confirm whether there is an absence of coplanarity in mass production. In instances in which an absence of coplanarity is detected, the notifying unit 128 may produce an alarm (e.g., audible alarm, light alarm, etc.) to alert personnel (e.g., an operator (e.g., on-duty operator)) to deal with the problem in real time. The coplanarity assist unit 100 may provide real-time monitoring (e.g., continuous monitoring) of the prober 30/tester head 40 coplanarity status, confirming whether to adjust the planarity of the tester head 40. The coplanarity assist unit 100 may also be deactivated by an operator to perform preventive maintenance (PM), repair or probe card replacement. The coplanarity assist unit 100 may also provide real-time monitoring of fabrication status, confirming whether an abnormal vibration or human impact might have caused a quality issue. The coplanarity assist unit 100 may also allow an operator of the semiconductor testing apparatus 200 to dig out the best recipe of production yield performance through big data analysis.

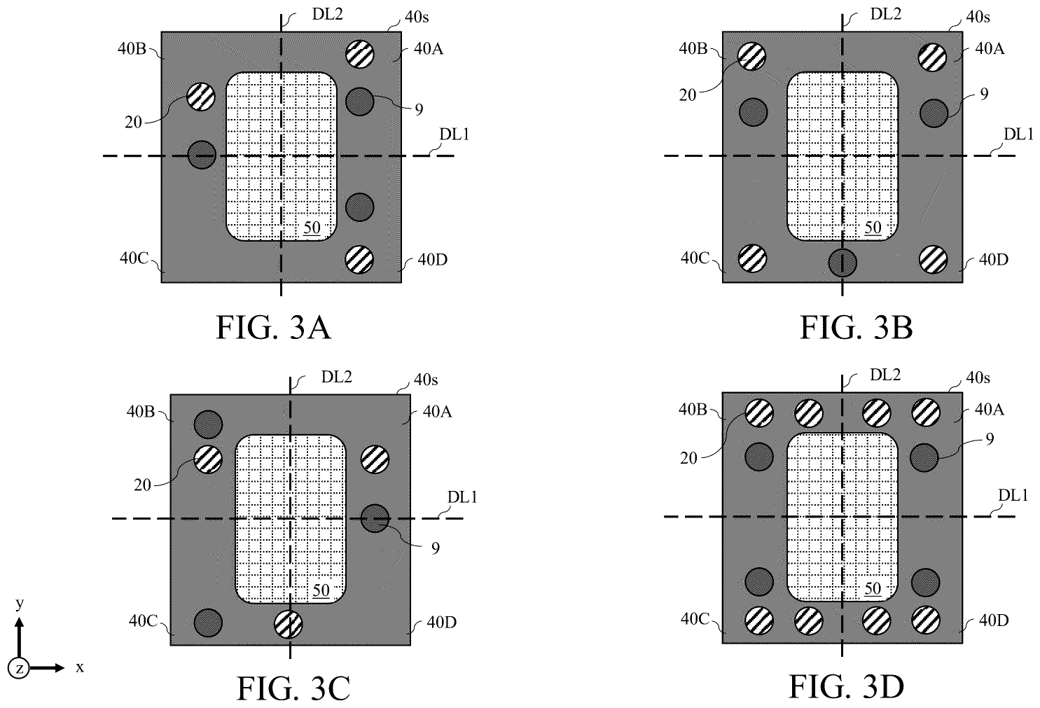

FIGS. 3A-3D are plan views (bottom-up views) of alternative layouts of the distance sensors and the guide holes 9 on the bottom surface 40s of the tester head 40 according to one or more embodiments. The distance sensors in FIGS. 3A-3D may be referred to collectively as distance sensors 20.

As illustrated in FIGS. 3A-3D, alternative layouts of the distance sensors 20 on the tester head 40 are within the contemplated scope of disclosure. A horizontal distance of any two of the distance sensors 20 may be greater than or equal to about 20 cm. A precision of the distance sensors 20 may be less than or equal to about 0.1 mm. A distance from the bottom surface 40s of the tester head 40 to the distance sensors 20 may be substantially equal for all of the distance sensors 20. This may help to ensure that the distance sensors 20 are substantially coplanar with the tester head 40 (e.g., bottom surface 40s of the tester head 40).

Generally, the tester head 40 may include a plurality of (e.g., three or more) distance sensors 20. The distance sensors 20 may be located in at least three different quadrants. Alternatively, one of the distance sensors 20 may be located on the first dividing line DL1 and the remaining distance sensors 20 (e.g., the two or more remaining distance sensors 20) may be located in two symmetrical quadrants opposite the distance sensor 20 on the first dividing line DL1. Alternatively, one of the distance sensors 20 may be located on the second dividing line DL2 and the remaining distance sensors 20 (e.g., the two or more remaining distance sensors 20) may be located in two symmetrical quadrants opposite the distance sensor 20 on the second dividing line DL2.

As illustrated in FIGS. 3A-3D, alternative layouts of the guide holes 9 in the tester head 40 are also within the contemplated scope of disclosure. Generally, the tester head 40 may include a plurality of (e.g., three or more) guide holes 9. The guide holes 9 may be located in each of the four quadrants. Alternatively, one of the guide holes 9 may be located on the first dividing line DL1 and the remaining guide holes 9 (e.g., the two or more remaining guide holes 9) may be located in two symmetrical quadrants opposite the distance sensor 20 on the first dividing line DL1. Alternatively, one of the guide holes 9 may be located on the second dividing line DL2 and the remaining guide holes 9 (e.g., the two or more remaining guide holes 9) may be located in two symmetrical quadrants opposite the distance sensor 20 on the second dividing line DL2.

FIG. 3A is a plan view of a first alternative layout of the distance sensors 20 and guide holes 9 on the bottom surface 40s of the tester head 40 according to one or more embodiments. In the first alternative layout, one of the distance sensors 20 is located in each of the first quadrant 40A, second quadrant 40B and fourth quadrant 40D. One of the guide holes 9 is located on the first dividing line DL1 between the second quadrant 40B and the third quadrant 40C, and one of the guide holes 9 is located in each of the first quadrant 40A and the fourth quadrant 40D.

FIG. 3B is a plan view of a second alternative layout of the distance sensors 20 and guide holes 9 on the bottom surface 40s of the tester head 40 according to one or more embodiments. In the second alternative layout, one of the distance sensors 20 is located in each of the first quadrant 40A, second quadrant 40B, third quadrant 40C and fourth quadrant 40D. One of the guide holes 9 is located on the second dividing line DL2 between the third quadrant 40C and the fourth quadrant 40D, and one of the guide holes 9 is located in each of the first quadrant 40A and the second quadrant 40B.

FIG. 3C is a plan view of a third alternative layout of the distance sensors 20 and guide holes 9 on the bottom surface 40s of the tester head 40 according to one or more embodiments. In the third alternative layout, one of the distance sensors 20 is located on the second dividing line DL2 between the third quadrant 40C and the fourth quadrant 40D, and one of the distance sensors 20 is located in each of the first quadrant 40A and the second quadrant 40B. One of the guide holes 9 is located on the first dividing line DL1 between the first quadrant 40A and the fourth quadrant 40D, and one of the guide holes 9 is located in each of the second quadrant 40B and the third quadrant 40C.

FIG. 3D is a plan view of a fourth alternative layout of the distance sensors 20 and guide holes 9 on the bottom surface 40s of the tester head 40 according to one or more embodiments. In the fourth alternative layout, a pair of the distance sensors 20 is located in each of the first quadrant 40A, second quadrant 40B, third quadrant 40C and fourth quadrant 40D. One of the guide holes 9 is located in each of the first quadrant 40A, second quadrant 40B, third quadrant 40C and fourth quadrant 40D.

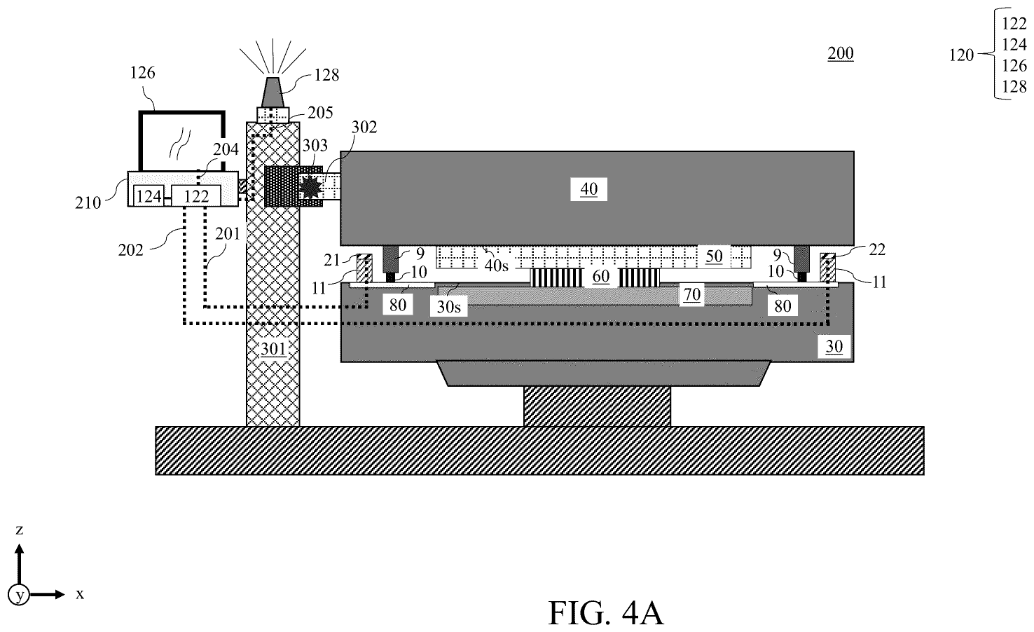

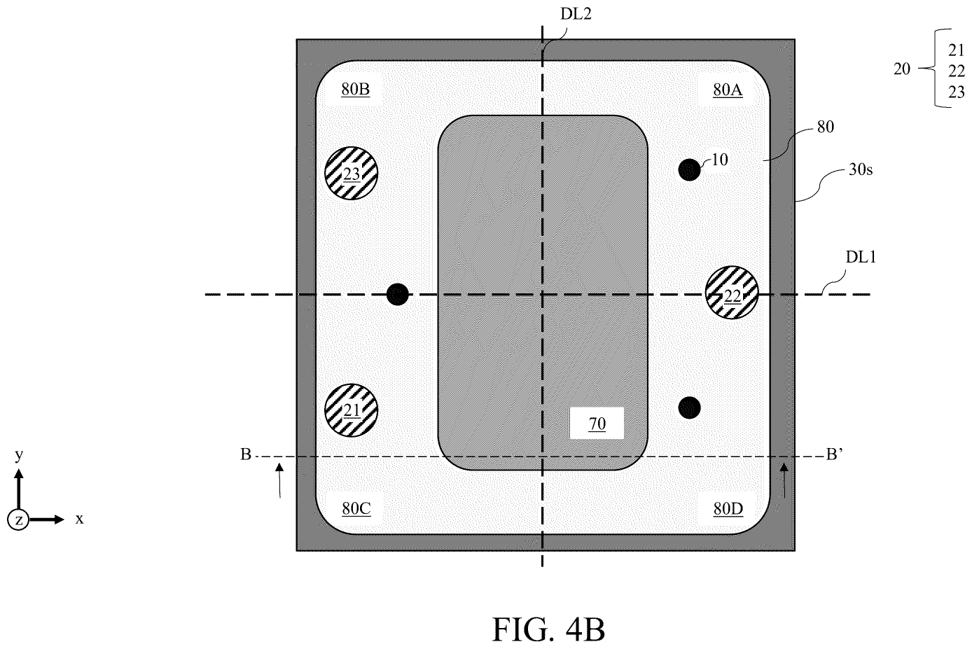

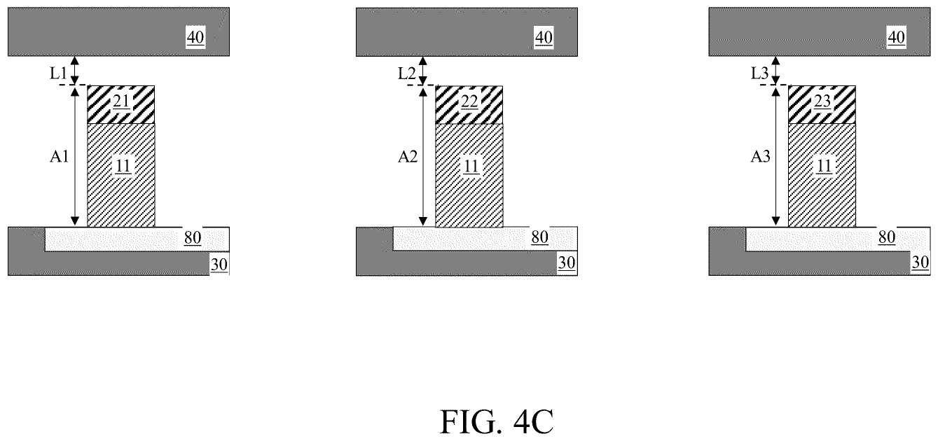

FIGS. 4A-4C are various views of a first alternative design of the semiconductor testing apparatus 200 including the coplanarity assist unit 100 according to one or more embodiments. FIG. 4A is a vertical cross-sectional view of the first alternative design of the semiconductor testing apparatus 200 according to one or more embodiments. FIG. 4B is a plan view (e.g., top-down view) of the prober 30 in the first alternative design of the semiconductor testing apparatus 200 according to one or more embodiments. The vertical cross-sectional view in FIG. 4A is in the y-direction along the line B-B′ in FIG. 4B. FIG. 4C is a detailed vertical cross-sectional view of the distance sensors in the first alternative design of the semiconductor testing apparatus 200 according to one or more embodiments.

The first alternative design of the semiconductor testing apparatus 200 may be substantially similar to the original design in FIGS. 2A-2C. However, as illustrated in FIG. 4A, the distance sensors 20 may be mounted on the prober 30 instead of the tester head 40. In particular, the sensor support frame 11 may be mounted on the upper surface of the prober head plane 80. The distance sensors 20 may be located on an upper end of the sensor support frame 11. An operation of the distance sensors 20 in the first alternative design in FIG. 4A may be substantially the same as the operation of the distance sensors 20 in the original design in FIG. 2A. In particular, the distance sensors 20 may detect a distance between the tester head 40 and the prober 30 (e.g., between the tester head 40 and the distance sensor 20).

The first wiring line 201 for transmitting the first distance signal may extend through the prober 30 and the prober head plane 80 into the sensor support frame 11 supporting the first distance sensor 21 to contact the first distance sensor 21. The second wiring line 202 for transmitting the second distance signal may also extend through the prober 30 and the proper head plane 80 into the sensor support frame 11 supporting the second distance sensor 22 to contact the second distance sensor 22. The third wiring line (not shown) for transmitting the third distance signal may also extend through the prober 30 and the proper head plane 80 into the sensor support frame 11 supporting the third distance sensor 23 to contact the third distance sensor 23.

Referring to FIG. 4B, the prober head plane 80 on the upper surface 30s of the prober 30 may be divided into four quadrants by the first dividing line DL1 extending in the x-direction and the second dividing line DL2 extending in the y-direction. The first dividing line DL1 and second dividing line DL2 may intersect at a centerpoint of the prober head plane 80. The first dividing line DL1 and second dividing line DL2 may divide the prober head plane 80 into a first quadrant 80A, a second quadrant 80B, a third quadrant 80C and a fourth quadrant 80D. The first quadrant 80A, second quadrant 80B, third quadrant 80C and fourth quadrant 80D may have substantially the same shape and substantially the same area. The mounting site for mounting the probe card 70 may be located in central region of the prober head plane 80. The centerpoint of the probe card 70 may be co-located with the centerpoint of the prober head plane 80.

As illustrated in FIG. 4B, the first distance sensor 21 may be located in the third quadrant 80C. The second distance sensor 22 may be located on the dividing line DL1 between the first quadrant 80A and the fourth quadrant 80D. The third distance sensor 23 may be located in the second quadrant 80B.

In at least one embodiment, the number of guide pins 10 in the semiconductor testing apparatus 200 may be the same as the number of distance sensors. As illustrated in FIG. 2B, the semiconductor testing apparatus 200 may include three guide pins 10. One of the guide pins 10 may be located in the fourth quadrant 80D. Another of the guide pins 10 may be located in the first quadrant 80A. Another of the guide pins 10 may be located on the first dividing line DL1 between the second quadrant 80B and the third quadrant 80C. The guide pins 10 on the prober 30 may be substantially aligned with the guide holes 9 on the tester head 40 in the z-direction.

Generally, the rules regarding number and location of the distance sensors 20 and the guide pins 10 in the four quadrants of the prober head plane 80 in FIG. 4B may be substantially the same as the rules regarding number and location of the distance sensors 20 and the guide holes 9 in the four quadrants of the lower surface 40s of the tester head 40 in FIG. 2B. Alternative layouts of the distance sensors 20 and the guide pins 10 similar to the layouts in FIGS. 3A-3D (with the prober head plane 80 being substituted for the lower surface 40s of the tester head 40, the guide pins 10 being substituted for the guide holes 9, etc.) are also within the contemplated scope of disclosure.

Referring to FIG. 4C a vertical cross-sectional view of the first distance sensor 21, second distance sensor 22 and third distance sensor 23 in the first alternative design of the semiconductor testing apparatus 200 is shown. Similar to the original design in FIG. 2C, in the first alternative design in FIG. 4C, the first distance sensor 21 may detect a first separation distance L1 between the prober head plane 80 and the tester head 40 (e.g., the first separation distance L1 between the tester head 40 and the first distance sensor 21) at a first location. The second distance sensor 22 may detect a second separation distance L2 between the prober head plane 80 and the tester head 40 (e.g., the second separation distance L2 between the tester head 40 and the second distance sensor 22) at a second location. The third distance sensor 23 may detect a third separation distance L3 between the prober head plane 80 and the tester head 40 (e.g., the third separation distance L3 between the tester head 40 and the third distance sensor 23) at a third location.

The calculations and other operations performed by the coplanarity determination module 122 in the first alternative design in FIGS. 4A-4C may be substantially the same as those performed by the coplanarity determination module 122 in the original design in FIGS. 2A-2C. In particular, if the coplanarity determination module 122 determines that L1+A1=L2+A2=L3+A3) then the coplanarity determination module 122 may determine that coplanarity exists between the tester head 40 and the prober 30. On the other hand, if the coplanarity determination module 122 determines that L1+A1L2+A2 and/or L1+A1/L3+A3), then the coplanarity determination module 122 may determine that coplanarity does not exist between the tester head 40 and the prober 30.

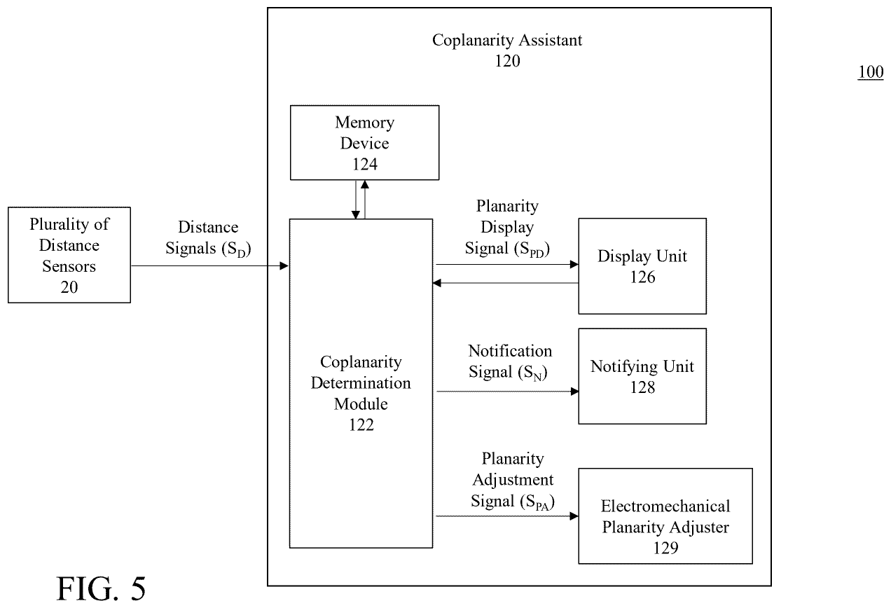

FIG. 5 is a schematic view of a first alternative design of the coplanarity assist unit 100 according to one or more embodiments. As illustrated in FIG. 5, the first alternative design of the coplanarity assist unit 100 may be substantially similar to the original design in FIG. 1. However, in the first alternative design, the coplanarity assistant 120 may additionally include an electromechanical planarity adjuster 129.

Similar to the original design in FIG. 1, in instances in which the coplanarity determination module 122 determines that coplanarity does not exist between the prober 30 and the tester head 40, then the coplanarity determination module 122 may determine what corrective action may be taken to set a coplanarity between the lower body and upper body based on the distance signals (SD). The corrective action may dictate, for example, that one side of the upper body should be raised by a given distance or lowered by a given distance to bring the lower body and upper body into coplanarity.

The coplanarity determination module 122 may then generate a planarity adjustment signal (SPA) for adjusting the planarity of the tester head 40 as dictated by the corrective action. The coplanarity determination module 122 may then transmit the planarity adjustment signal (SPA) by a wired connection of by a wireless connection to the electromechanical planarity adjuster 129. The electromechanical planarity adjuster 129 may respond to the planarity adjustment signal (SPA) by taking the corrective action specified by the planarity adjustment signal (SPA). For example, the electromechanical planarity adjuster 129 might raise one side of the tester head 40 by a given distance or lower one side of the tester head 40 by a given distance to bring the prober 30 and tester head 40 into coplanarity.

In at least one embodiment, the electromechanical planarity adjuster 129 may automatically take the corrective action specified by the planarity adjustment signal (SPA). That is, there may be no intervening steps required by the operator for the electromechanical planarity adjuster 129 to take the corrective action. In at least one embodiment, the coplanarity determination module 122 may cause the display unit 126 to display a message asking the operator if the operator desires the electromechanical planarity adjuster 129 to take the corrective action. In that case, the electromechanical planarity adjuster 129 may take the corrective action only on condition of an affirmative input by the operator.

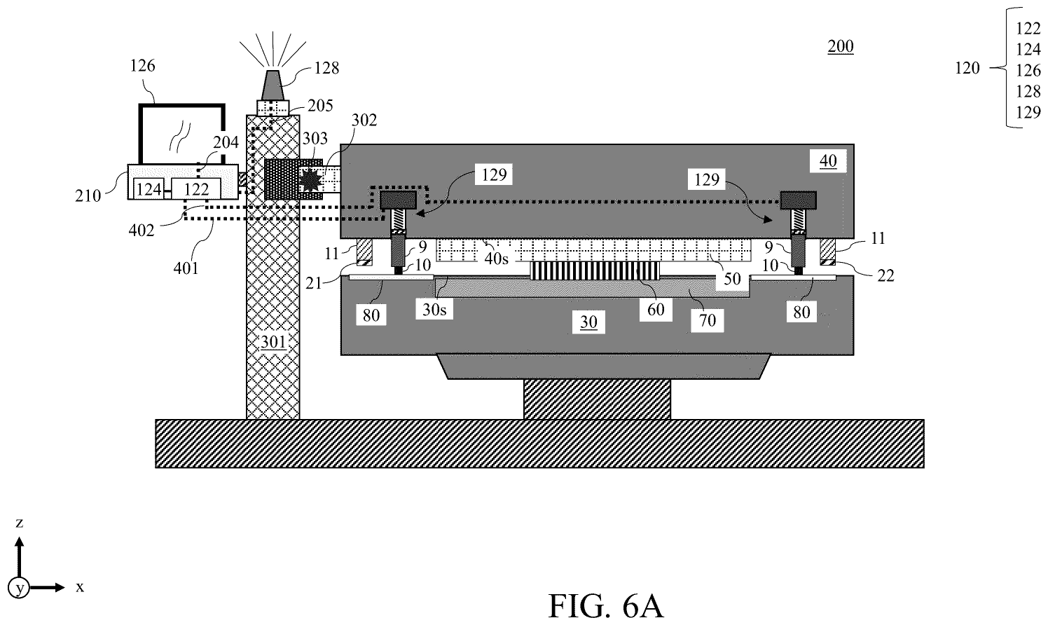

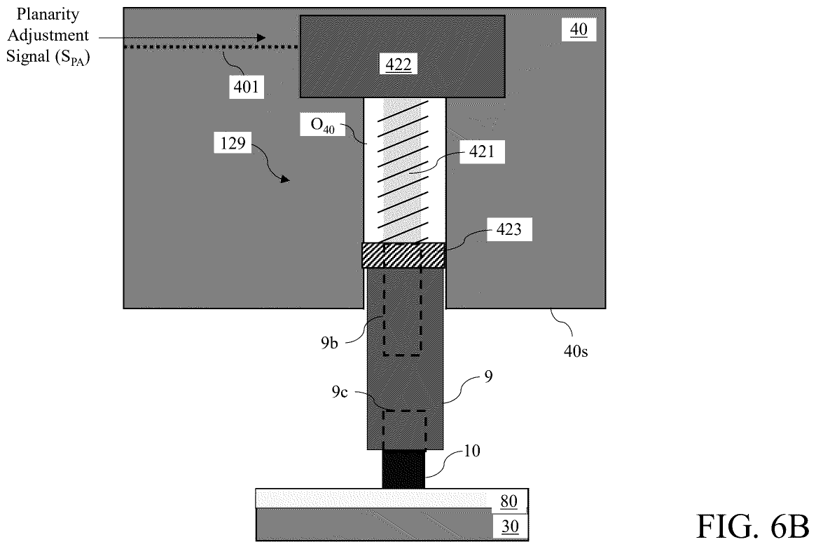

FIG. 6A is a vertical cross-sectional view of a second alternative design of the semiconductor testing apparatus 200 according to one or more embodiments. The first alternative design of the semiconductor testing apparatus 200 may be substantially similar to the original design in FIGS. 2A-2C. However, as illustrated in FIG. 6A, the second alternative design of the semiconductor testing apparatus 200 may include the first alternative design of the coplanarity assist unit 100 in FIG. 5. In particular, the coplanarity assist unit 100 in FIG. 6A may include a plurality of (e.g., three or more) electromechanical planarity adjusters 129. It should be noted that the first wiring line 201 and second wiring line 202 have been omitted from FIG. 6A for ease of explanation.

As illustrated in FIG. 6A, the electromechanical planarity adjusters 129 may be connected to the guide holes 9 that project down from the lower surface 40s of the tester head 40. The lower surface 40s of the tester head 40 in FIG. 6A may have substantially the same layout as the layout in FIG. 2B. In particular, the tester head 40 may include three guide holes 9 projecting down from the lower surface 40s. The electromechanical planarity adjusters 129 may independently raise or lower each of the three guide holes 9 under the control of the coplanarity determination module 122.

The coplanarity determination module 122 may transmit a first planarity adjustment signal (SPA) over a first planarity adjustment wiring line 401 to one of the electromechanical planarity adjusters 129. The first planarity adjustment wiring line 401 may extend through the tester head 40 to the electromechanical planarity adjuster 129. The coplanarity determination module 122 may also transmit a second planarity adjustment signal over a second planarity adjustment wiring line 402 to a second one of the electromechanical planarity adjusters 129. The second planarity adjustment wiring line 402 may also extend through the tester head 40 to the electromechanical planarity adjuster 129. The coplanarity determination module 122 may also transmit a third planarity adjustment signal (SPA) over a third planarity adjustment wiring line (not shown) to third one of the electromechanical planarity adjusters 129. The third planarity adjustment wiring line may also extend through the tester head 40 to the electromechanical planarity adjuster 129.

FIG. 6B is a vertical cross-sectional view of the electromechanical planarity adjuster 129 according to one or more embodiments. The electromechanical planarity adjuster 129 may include, for example, a linear actuator. The electromechanical planarity adjuster 129 may include other types of electromechanical devices within the contemplated scope of disclosure. As illustrated in FIG. 6B, the electromechanical planarity adjuster 129 may include a threaded shaft 421 and an electric motor 422 attached to the threaded shaft 129. The threaded shaft 421 may extend in the z-direction in an opening O40 in the lower surface 40s of the tester head 40. The electric motor 422 may be fixed at an upper end of the opening O40. The electric motor 422 may rotate the threaded shaft 129 clockwise or counterclockwise.

The electromechanical planarity adjuster 129 may also include a nut 423 that is fixed to an upper end of the guide hole 9. The nut 423 may also be slidably fixed to a sidewall of the opening O40. In at least one embodiment, the sidewall of the opening O40 may include one or more grooves extending up and down along the opening O40 and a portion of the nut 423 may be located in the grooves. The guide hole 9 may include an opening 9b and the threaded shaft 421 may move in and out of the opening 9b.

The planarity adjustment signal (SPA) transmitted from the from the coplanarity determination module 122 may include a drive signal (drive voltage) for driving the electric motor 422. Depending on the drive signal, the electric motor 422 may drive the threaded shaft 421 to rotate clockwise or counterclockwise causing the nut 423 to ride up and down the threads of the threaded shaft 421 in the corresponding direction. This may provide an extension and retraction capability to the guide hole 9.

Thus, for example, by rotating the threaded shaft 421 clockwise the guide hole 9 may be retracted into the opening O40. This may allow a side of the tester head 40 to be lowered down toward the prober 30. By rotating the threaded shaft 421 counterclockwise the guide hole 9 may be extended out of the opening O40. This may cause the guide hole 9 to contact an upper surface of the guide pin 10 in a lower opening 9c in the guide hole 9, creating an upward force on the side of the tester head 40. The electromechanical planarity adjuster 129 may thereby be used to adjust a planarity of the tester head 40 so as to set a coplanarity between the tester head 40 and the prober 30.

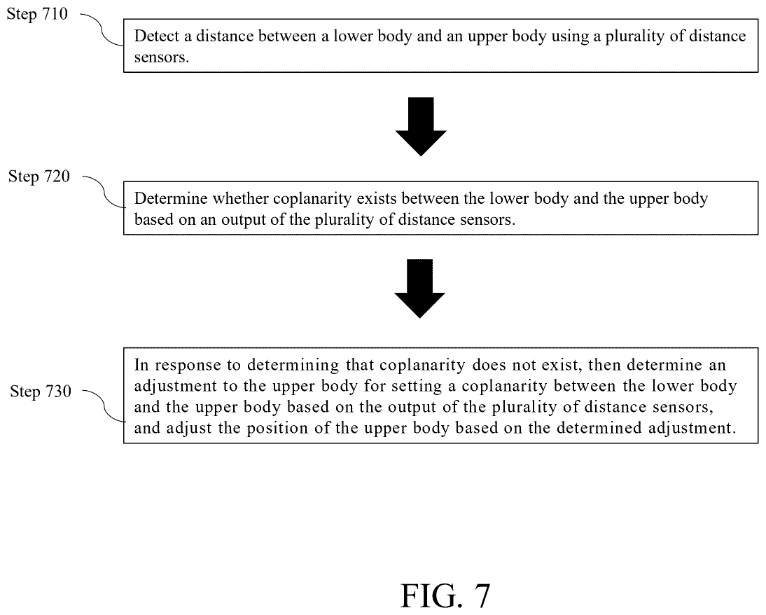

FIG. 7 is a flowchart illustrating a method of setting coplanarity according to one or more embodiments. Step 710 of the method may include detecting a distance between a lower body and an upper body. Step 720 may include determining whether coplanarity exists between the lower body and the upper body based on an output of the plurality of distance sensors. Step 730 may include if it is determined that coplanarity does not exist, then determining an adjustment to the upper body for setting a coplanarity between the lower body and the upper body based on the output of the plurality of distance sensors, and adjusting the planarity of the upper body based on the determined adjustment.

Referring to FIGS. 1-7, a coplanarity assist unit 100 may include a plurality of distance sensors 20 mounted on at least one of a lower body 30 or a upper body 40 at a plurality of locations, respectively, wherein each of the plurality of distance sensors 20 may be configured to detect a distance between the lower body 30 and the upper body 40 at the plurality of locations, and a coplanarity assistant 120 configured to determine based on an output of the plurality of distance sensors 20 whether coplanarity exists between the lower body 30 and the upper body 40 and assist with the position of the lower body 30 and the upper body 40 in order to set the coplanarity between the lower body 30 and the upper body 40.

In one embodiment, the output of the plurality of distance sensors 20 may include a plurality of distance signals (SD) transmitted from the plurality of distance sensors 20, respectively. In one embodiment, the coplanarity assistant 120 may include a coplanarity determination module 122 configured to determine whether coplanarity exists between the lower body 30 and the upper body 40 based on the plurality of distance signals (SD). In one embodiment, the coplanarity assistant 120 may further include a display unit 126 configured to display adjustment data for adjusting a planarity of the upper body 40 to set a coplanarity between the lower body 30 and the upper body 40. In one embodiment, the coplanarity determination module 122 may be configured to generate a planarity display signal (SPD) based on the plurality of distance signals (SD), and the display unit 126 may be configured to display the adjustment data to the planarity of the upper body 40 based on the planarity display signal (SPD). In one embodiment, the coplanarity determination module 122 may be configured to continuously update a display of the adjustment data on the display unit 126 to reflect an adjustment to the position of the upper body 40 by an operator. In one embodiment, the coplanarity assistant 120 may further include an electromechanical planarity adjuster 129 configured to adjust the position of the upper body 40. In one embodiment, the coplanarity determination module 122 may be configured to generate a planarity adjustment signal (SPA) based on the plurality of distance signals (SD), the electromechanical planarity adjuster 129 may be configured to adjust the position of the upper body 40 based on the planarity adjustment signal (SPA). In one embodiment, the coplanarity determination module 122 may be configured to continuously update a display of the adjustment data on the display unit 126 to reflect an adjustment to the planarity of the upper body 40 by the electromechanical planarity adjuster 129.

Referring again to FIGS. 1-7, a semiconductor testing apparatus 200 may include a prober 30 configured to support a probe card 70, a tester head 40 configured to support a device under test (DUT) 50, and a coplanarity assist unit 100 including a plurality of distance sensors 20 and configured to determine whether coplanarity exists between the prober 30 and the tester head 40 and assist with setting coplanarity between the prober 30 and tester head 40 based on an output of the plurality of distance sensors 20.

In one embodiment, the plurality of distance sensors 20 may be mounted on at least one of the prober 30 or the tester head 40 and may be configured to determine a distance between the tester head 40 and the prober 30 at a plurality of locations. In one embodiment, the plurality of distance sensors 20 may include at least one of a laser sensor, an ultrasonic sensor, an infrared sensor, an inductive sensor, a light-emitting diode (LED) sensor, a light detection and ranging (LIDAR) device, or a vertical cavity surface emitting laser (VCSEL) sensor. In one embodiment, the coplanarity assist unit 100 may further include a plurality of sensor support frame 11 and the plurality of distance sensors 20 may be located on the plurality of sensor support frame 11, respectively. In one embodiment, the prober 30 may include a prober head plane 80 on an upper surface of the prober 30, and the plurality of distance sensors 20 may be configured to determine a distance between the tester head 40 and the prober head plane 80. In one embodiment, the semiconductor testing apparatus 200 may further include a guide hole 9 on a lower surface of the tester head 40, and a guide pin 10 on the prober head plane 80 and configured to be inserted in the guide hole 9. In one embodiment, the plurality of distance sensors 20 may be located on a lower surface of the tester head 40 which may be divided into four quadrants by a first dividing line DL1 and a second dividing line DL2 perpendicular to the first dividing line DL1, and an arrangement of the plurality of distance sensors 20 may include one of a first arrangement in which the plurality of distance sensors 20 may be located in at least three quadrants of the four quadrants, a second arrangement in which one distance sensor of the plurality of distance sensors 20 may be located on the first dividing line DL1, and a remainder of the plurality of distance sensors 20 may be located opposite the one distance sensor in two quadrants that are symmetrical with respect to the first dividing line DL1, or a third arrangement in which one distance sensor of the plurality of distance sensors 20 may be located on the second dividing line DL2, and a remainder of the plurality of distance sensors 20 may be located opposite the one distance sensor in two quadrants that are symmetrical with respect to the second dividing line DL2. The plurality of distance sensors 20 may include a first distance sensor 21 on a first sensor support frame 11 at a first location, wherein the first distance sensor 21 and first sensor support frame 11 have a first combined length A1, and the first distance sensor 21 may be configured to detect a first separation distance L1 between the prober head plane 80 and the first distance sensor 21 at the first location, a second distance sensor 22 on a second sensor support frame 11 at a second location, wherein the second distance sensor 22 and second sensor support frame 11 have a second combined length A2, and the second distance sensor 22 may be configured to detect a second separation distance L2 between the prober head plane 80 and the second distance sensor 22 at the second location, and a third distance sensor 23 on a third sensor support frame 11 at a third location, wherein the third distance sensor 23 and third sensor support frame 11 have a third combined length A3, and the third distance sensor 23 may be configured to detect a third separation distance L3 between the prober head plane 80 and the third distance sensor 23 at the third location. In one embodiment, the coplanarity assist unit 100 may further include a coplanarity assistant 120 including a display unit 126 configured to display adjustment data for adjusting a planarity of the tester head 40 to set a coplanarity between the prober 30 and the tester head 40, and a coplanarity determination module 122 configured to compare a first sum of the first combined length A1 and first separation distance L1 to a second sum of the second combined length A2 and second separation distance L2 and to a third sum of the third combined length A2 and third separation distance L3, determine that coplanarity may be achieved when the first sum may be substantially equal to the second sum and substantially equal to the third sum, and generate a planarity display signal (SPD) based on the plurality of distance signals (SD), wherein the display unit 126 may be configured to display the adjustment data based on the planarity display signal (SPD). In one embodiment, the coplanarity determination module 122 may be configured to generate a planarity adjustment signal (SPA) based on the plurality of distance signals (SD), and the coplanarity assistant 120 may further include an electromechanical planarity adjuster 129 configured to adjust the planarity of the tester head 40 based on the planarity adjustment signal (SPA).

Referring again to FIGS. 1-7, a method of setting coplanarity may include detecting a distance between a lower body 30 and an upper body 40, determining whether coplanarity exists between the lower body 30 and the upper body 40 based on an output of the plurality of distance sensors 20, and in response to determining that coplanarity does not exist, then determining an adjustment to the upper body 40 for setting a coplanarity between the lower body 30 and the upper body 40 based on the output of the plurality of distance sensors 20, and adjusting the position of the upper body 40 based on the determined adjustment.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A coplanarity assist unit, comprising:
a plurality of distance sensors mounted on at least one of a lower body or a upper body at a plurality of locations, respectively, wherein each of the plurality of distance sensors are configured to detect a distance between the lower body and the upper body at the plurality of locations; and
a coplanarity assistant configured to determine based on an output of the plurality of distance sensors whether coplanarity exists between the lower body and the upper body and assist with a position of the lower body and the upper body in order to set the coplanarity between the lower body and the upper body.

2. The coplanarity assist unit of claim 1, wherein the output of the plurality of distance sensors comprises a plurality of distance signals transmitted from the plurality of distance sensors, respectively.

3. The coplanarity assist unit of claim 2, wherein the coplanarity assistant comprises a coplanarity determination module configured to determine whether coplanarity exists between the lower body and the upper body based on the plurality of distance signals.

4. The coplanarity assist unit of claim 3, wherein the coplanarity assistant further comprises a display unit configured to display adjustment data for adjusting a position of the upper body to set a coplanarity between the lower body and the upper body.

5. The coplanarity assist unit of claim 4, wherein the coplanarity determination module is configured to generate a planarity display signal based on the plurality of distance signals, and the display unit is configured to display the adjustment data for adjusting the position of the upper body based on the planarity display signal.

6. The coplanarity assist unit of claim 5, wherein the coplanarity determination module is configured to continuously update a display of the adjustment data on the display unit to reflect an adjustment to the position of the upper body by an operator.

7. The coplanarity assist unit of claim 4, wherein the coplanarity assistant further comprises an electromechanical planarity adjuster configured to adjust the position of the upper body.

8. The coplanarity assist unit of claim 7, wherein the coplanarity determination module is configured to generate a planarity adjustment signal based on the plurality of distance signals, the electromechanical planarity adjuster is configured to adjust the planarity of the upper body based on the planarity adjustment signal.

9. The coplanarity assist unit of claim 8, wherein the coplanarity determination module is configured to continuously update a display of the adjustment data on the display unit to reflect an adjustment to the planarity of the upper body by the electromechanical planarity adjuster.

10. A semiconductor testing apparatus, comprising:
a prober configured to support a probe card;
a tester head configured to support a device under test (DUT); and
a coplanarity assist unit comprising a plurality of distance sensors and configured to determine based on an output of the plurality of distance sensors whether coplanarity exists between the prober and the tester head and to assist with setting a position of a lower body and a upper body in order to set the coplanarity between the lower body and the upper body.

11. The semiconductor testing apparatus of claim 10, wherein the plurality of distance sensors are mounted on at least one of the prober or the tester head and are configured to determine a distance between the tester head and the prober at a plurality of locations.

12. The semiconductor testing apparatus of claim 10, wherein the plurality of distance sensors comprises at least one of a laser sensor, an ultrasonic sensor, an infrared sensor, an inductive sensor, a light-emitting diode (LED) sensor, a light detection and ranging (LIDAR) device, or a vertical cavity surface emitting laser (VCSEL) sensor.

13. The semiconductor testing apparatus of claim 10, wherein the coplanarity assist unit further comprises a plurality of sensor support frames and the plurality of distance sensors are located on the plurality of sensor support frames, respectively.

14. The semiconductor testing apparatus of claim 10, wherein the prober comprises a prober head plane on an upper surface of the prober, and the plurality of distance sensors are configured to determine a distance between the tester head and the prober head plane.

15. The semiconductor testing apparatus of claim 10, further comprising:
a guide hole on a lower surface of the tester head; and
a guide pin on the prober head plane and configured to be inserted in the guide hole.

16. The semiconductor testing apparatus of claim 10, wherein the plurality of distance sensors are located on a lower surface of the tester head which is divided into four quadrants by a first dividing line and a second dividing line perpendicular to the first dividing line, and an arrangement of the plurality of distance sensors comprises one of:
a first arrangement in which the plurality of distance sensors are located in at least three quadrants of the four quadrants;
a second arrangement in which one distance sensor of the plurality of distance sensors is located on the first dividing line, and a remainder of the plurality of distance sensors is located opposite the one distance sensor in two quadrants that are symmetrical with respect to the first dividing line; or
a third arrangement in which one distance sensor of the plurality of distance sensors is located on the second dividing line, and a remainder of the plurality of distance sensors is located opposite the one distance sensor in two quadrants that are symmetrical with respect to the second dividing line.

17. The semiconductor testing apparatus of claim 10, wherein the plurality of distance sensors comprises:
a first distance sensor on a first sensor support frame at a first location, wherein the first distance sensor and first sensor support frame have a first combined length, and the first distance sensor is configured to detect a first separation distance between a prober head plane and the first distance sensor at the first location;
a second distance sensor on a second sensor support frame at a second location, wherein the second distance sensor and second sensor support frame have a second combined length, and the second distance sensor is configured to detect a second separation distance between the prober head plane and the second distance sensor at the second location; and
a third distance sensor on a third sensor support frame at a third location, wherein the third distance sensor and third sensor support frame have a third combined length, and the third distance sensor is configured to detect a third separation distance between the prober head plane and the third distance sensor at the third location.

18. The semiconductor testing apparatus of claim 17, wherein the coplanarity assist unit further comprises a coplanarity assistant comprising:
a display unit configured to display adjustment data for adjusting a planarity of the tester head to set a coplanarity between the prober and the tester head; and
a coplanarity determination module configured to:
compare a first sum of the first combined length and first separation distance to a second sum of the second combined length and second separation distance and to a third sum of the third combined length and third separation distance;
determine that coplanarity is achieved when the first sum is substantially equal to the second sum and substantially equal to the third sum; and
generate a planarity display signal based on a plurality of distance signals, wherein the display unit is configured to display the adjustment data based on the planarity display signal.

19. The semiconductor testing apparatus of claim 18, wherein the coplanarity determination module is configured to generate a planarity adjustment signal based on the plurality of distance signals, and the coplanarity assistant further comprises an electromechanical planarity adjuster configured to adjust the planarity of the tester head based on the planarity adjustment signal.

20. A method of setting coplanarity, the method comprising:
detecting a distance between a lower body and an upper body;
determining whether coplanarity exists between the lower body and the upper body based on an output of the plurality of distance sensors; and
in response to determining that coplanarity does not exist:
determining an adjustment to a position of the upper body for setting a coplanarity between the lower body and the upper body based on the output of the plurality of distance sensors; and
adjusting the position of the upper body based on the determined adjustment to the adjustment to the position of the upper body.
